(19) United States
(12) Patent Application Publication
(10) Pub. No.: US 2021/0296114 A1
(43) Pub. Date: Sep. 23, 2021

(54) THIN FILM FORMING DEVICE AND THIN FILM FORMING METHOD USING THE SAME

(71) Applicant: JUSUNG ENGINEERING CO., LTD., Gwangju-si, Gyeonggi-do (KR)

(72) Inventors: Bun Hei KOO, Seoul (KR); Chul-Joo HWANG, Seongnam-si, Gyeonggi-do (KR)

(21) Appl. No.: 17/262,199

(22) PCT Filed: Aug. 21, 2019
(86) PCT No.: PCT/KR2019/010656

§ 371 Date: Jan. 21, 2021

(30) Foreign Application Priority Data
Aug. 21, 2018 (KR) 10-2018-0097671

(51) Int. Cl. H01L 21/02; H01L 21/66; H01J 37/32; C23C 16/455; C23C 16/50; C23C 16/458; C23C 16/24; C23C 16/52

(52) U.S. Cl. CPC H01L 21/0262; H01L 21/02592; H01L 21/02598; H01L 21/02532; H01L 21/02661; H01L 22/26; H01J 2237/332; C23C 16/45536; C23C 16/50; C23C 16/4584; C23C 16/24; C23C 16/52; H01J 37/3244

(57) ABSTRACT

The disclosure relates to a thin film forming device and a thin film forming method using the same capable of improving the film quality of a silicon thin film by dividing a reaction space in a process chamber of the thin film forming device and thereby forming the silicon thin film on a substrate in a first space and treating a surface of the silicon thin film, formed in the first space, in a second space by using plasma. By the thin film forming device and the thin film forming method using the same according to the disclosure, with a trend that a pattern is complicated and the depth of the pattern increases, impurities in a thin film may be more efficiently removed, a uniform thin film may be formed on a pattern, and the grain size of the crystals of a silicon thin film may be made uniform.

### BACKGROUND

### 1. Technical Field

Various embodiments generally relate to a thin film forming device and a thin film forming method using the same, and more particularly, to a thin film forming device and a thin film forming method using the same capable of improving the film quality of a silicon thin film by dividing a reaction space in a process chamber of the thin film forming device and thereby forming the silicon thin film on a substrate in a first space and treating a surface of the silicon thin film, formed in the first space, in a second space by using plasma.

### 2. Related Art

In general, in order to form a thin film having a predetermined thickness on a substrate such as a semiconductor wafer, a glass or the like, thin film forming methods employing physical vapor deposition (PVD) using physical collisions such as sputtering, chemical vapor deposition (CVD) using chemical reactions, atomic layer deposition (ALD), and so forth are used.

As the CVD, atmospheric pressure CVD (APCVD), low pressure CVD (LPCVD) and plasma enhanced CVD (PECVD) may be used. Among these, the PECVD is widely used because of advantages that low temperature deposition is possible and a thin film forming speed is fast.

Meanwhile, the use of the ALD that may substantially uniformly form a fine pattern having an atomic layer thickness and has excellent step coverage is being increased.

FIG. 1 is a representation of an example of a flow chart to assist in the explanation of a silicon thin film forming method according to the conventional art.

Referring to FIG. 1, the silicon thin film forming method according to the conventional art includes amorphous silicon film forming step S10, plasma post-treatment step S20 and purge and pumping step S30.

In the amorphous silicon film forming step S10 as step of forming an amorphous silicon thin film on a substrate in a chamber, the silicon thin film is formed through a CVD or ALD process by supplying an SixHy-based mono-, di- or tri-silane gas as a source gas on the substrate.

In the plasma post-treatment step S20, a top surface portion of the amorphous silicon film is surface-treated using nitrous oxide plasma, nitrogen monoxide plasma, ammonia plasma, or the like.

Then, in the purge and pumping step S30, a purge gas is supplied into the chamber to purge and pump the inside of the chamber.

As described above, in the conventional silicon thin film forming method, after the silicon film having a desired thickness is formed by performing the amorphous silicon film forming step S10 in the chamber, the surface treatment of the silicon film is performed using the plasma.

However, in a substrate which is formed with a pattern, as a line width of the pattern narrows and an aspect ratio increases, it is difficult to form or grow a uniform silicon thin film on the pattern.

As such, as a line width of the pattern narrows and an aspect ratio increases, it is difficult to form or grow a silicon thin film having a uniform or appropriate step coverage on the top, side and bottom of the pattern, by a thin film forming method generally known in the conventional art. Also, it is substantially difficult to uniformly remove impurities in the silicon thin film formed on the top, side and bottom of the pattern.

Therefore, structural improvement has been demanded to form a uniform thin film on a fine pattern and remove impurities in the thin film to thereby form the thin film having excellent characteristics.

### SUMMARY

Various embodiments are directed to a thin film forming device and a thin film forming method using the same capable of improving the film quality of a silicon thin film by dividing a reaction space in a process chamber of the thin film forming device and thereby forming the silicon thin film on a substrate in a first space and treating a surface of the silicon thin film, formed in the first space, in a second space by using plasma.

Also, various embodiments are directed to a device and a method capable of forming a uniform thin film on a pattern by removing impurities in the thin film, with a trend that the pattern is complicated and the depth of the pattern increases, and making the grain sizes of the crystals of a silicon thin film uniform.

In an embodiment, a thin film forming device may include: a process chamber providing a reaction space; a substrate support installed in the process chamber and supporting a substrate; a chamber lid covering a top of the process chamber; and a gas injection module installed on a bottom surface of the chamber lid, and injecting a process gas to the substrate, the reaction space including: a first space for forming a silicon thin film on the substrate; and a second space for processing a surface of the substrate which is formed with the silicon thin film, by using plasma.

In an embodiment, a thin film forming method may include: silicon thin film forming step of forming a silicon thin film by supplying a silicon source gas on a substrate in a first space in a process chamber; first purge gas supply step of supplying a first purge gas;

plasma surface treatment step of treating a surface of the silicon thin film by using plasma in a second space in the process chamber to remove impurities in the silicon thin film or make a grain size of the silicon thin film uniform; and second purge gas supply step of supplying a second purge gas.

In an embodiment, a thin film forming method may include: plasma pre-treatment step of treating a surface of a substrate by using plasma in a second space in a process chamber to remove a natural oxide film formed on the surface or impurities included in the surface of the substrate; second purge gas supply step of supplying a second purge gas; silicon thin film forming step of forming a silicon thin film by supplying a silicon source gas on the substrate in a first space in the process chamber; first purge gas supply step of supplying a first purge gas; plasma surface treatment step of treating a surface of the silicon thin film by using plasma in the second space in the process chamber to remove impurities in the silicon thin film or make a grain size of the silicon thin film uniform; and second purge gas supply step of supplying a second purge gas.

In the thin film forming device and the thin film forming method using the same according to the embodiments of the disclosure, by dividing a reaction space of the thin film forming device and thereby forming or growing a silicon thin film on a substrate in a first space and treating a surface of the silicon thin film, formed in the first space, in a second space by using plasma, impurities in the silicon thin film may be removed and the grain sizes of the crystals of the silicon thin film may be made uniform, whereby an advantage is provided in that the silicon thin film with excellent characteristics may be obtained.

### BRIEF DESCRIPTION OF THE DRAWINGS

FIG. 1 is a representation of an example of a flow chart to assist in the explanation of a silicon thin film forming method according to the conventional art.

FIG. 2 is a representation of an example of a view to assist in the explanation of a planar structure in a chamber of a thin film forming device in accordance with an embodiment of the disclosure.

FIG. 3 is a sectional view taken along the line A-A of FIG. 2, schematically illustrating the chamber.

FIG. 4 is a representation of an example of a flow chart to assist in the explanation of a thin film forming method in accordance with an embodiment of the disclosure.

FIG. 5 is a representation of an example of a flow chart to assist in the explanation of a thin film forming method in accordance with another embodiment of the disclosure.

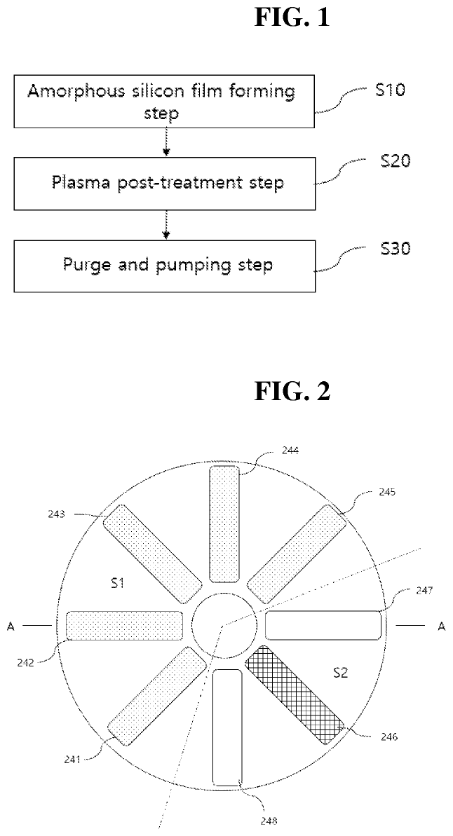

### DETAILED DESCRIPTION

Hereinafter, various embodiments will be described in detail with reference to the accompanying drawings to the extent that a person skilled in the art to which the embodiments pertain may easily enforce the embodiments. Among the reference numerals presented in the drawings, like reference numerals denote like members.

In describing the present disclosure, when it is determined that the detailed description of the known related art may obscure the gist of the present disclosure, the detailed description thereof will be omitted.

Although the terms such as first and second may be used to describe various components, the components are not limited by the terms, and the terms are used only to distinguish components from other components.

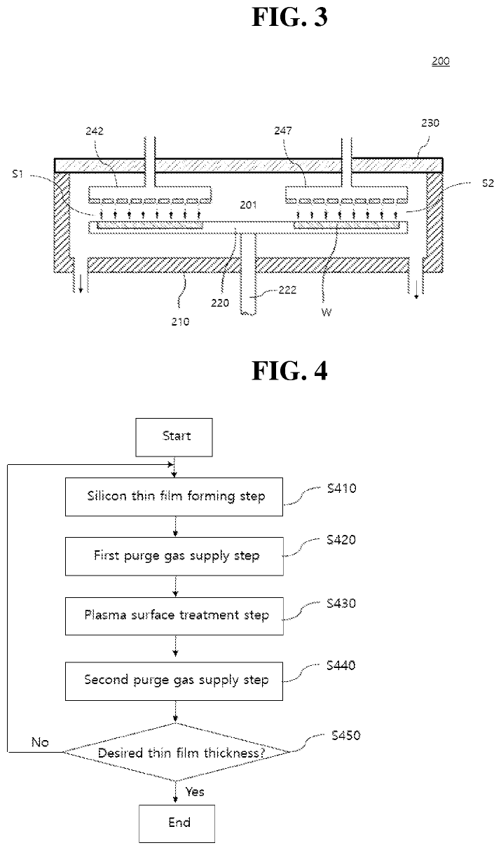

FIG. 2 is a representation of an example of a view to assist in the explanation of a planar structure in a chamber of a thin film forming device in accordance with an embodiment of the disclosure, and FIG. 3 is a sectional view taken along the line A-A of FIG. 2, schematically illustrating the chamber.

Referring to FIGS. 2 and 3, a thin film forming device 200 in accordance with an embodiment of the disclosure includes a process chamber 210 which provides a reaction space 201, a substrate support 220 which is installed in the process chamber 210 and supports substrates W, a chamber lid 230 which covers the top of the process chamber 210, and a gas injection module 240 which is installed on the bottom surface of the chamber lid 230 and injects process gases to the substrates W.

The process chamber 210 forms the reaction space 201 together with the chamber lid 230, and accommodates therein the substrate support 220 and the gas injection module 240.

The reaction space 201 includes a first space S1 in which a silicon thin film is formed on substrates W and a second space S2 in which the surfaces of the substrates W formed with the silicon thin film are treated by using plasma.

The substrate support 220 supports the plurality of substrates W and positions the substrates W in the first space S1 and the second space S2 while being rotated about a rotation shaft 222 lying thereunder.

The first space S1 corresponds to a silicon forming region where the silicon thin film is formed on the substrates W by chemical vapor deposition (CVD), atomic layer deposition (ALD) or selective epitaxial growth.

The second space S2 corresponds to a plasma treatment region where the silicon thin film formed on the substrates W is exposed to plasma of an inert gas and thereby impurities in the silicon thin film are removed or the grain sizes of the crystals of the silicon thin film are made uniform.

The gas injection module 240 which injects the process gases to the substrates W is disposed over the substrate support 220 and under the chamber lid 230.

The gas injection module 240 includes source gas injection parts 241 to 245, a plasma gas injection part 246 and purge gas injection parts 247 and 248.

The source gas injection parts 241 to 245 inject a silicon source gas to the substrates W in the first space S1, and thereby, form the silicon thin film on the substrates W. In the source gas injection parts 241 to 245, in addition to the silicon source gas, a carrier gas such as hydrogen, argon or nitrogen may be introduced together with the silicon source gas and may be injected onto the substrates W.

The plasma gas injection part 246 injects a plasma gas to the substrate W in the second space S2. As the plasma gas, at least one gas among hydrogen (H₂), nitrogen (N₂), argon (Ar) and an inert gas may be used.

The purge gas injection parts 247 and 248 inject a purge gas between the first space S1 and the second space S2, and thereby, separate the first space S1 and the second space S2. By the purge gas injected from the purge gas injection parts 247 and 248, the reaction space 201 over the substrate support 220 on which the plurality of substrates W are placed is divided into the first space S1 being the silicon forming region and the second space S2 being the plasma treatment region.

While not illustrated in a drawing, a region where the purge gas is injected between the first space S1 and the second space S2 and thereby removes the source gas remaining over the substrate W may be defined as a first purge space, and a region where the purge gas is injected between the second space S2 and the first space S1 and thereby removes the plasma gas remaining over the substrate W may be defined as a second purge space.

The first space S1, the first purge space, the second space S2 and the second purge space correspond to physically separated spaces. Further, the first space S1, the first purge space, the second space S2 and the second purge space may be spaces separated in terms of time, in which silicon formation, purge, plasma surface treatment and purge are performed with time differences.

When a nitrogen (N₂) gas is decomposed or excited into radicals, it may act as a dopant being an impurity in the formation or growth of a silicon film, and thereby, may adversely affect a film quality. Therefore, care is required in using the nitrogen (N₂) gas as the carrier gas of the silicon source gas or the plasma gas.

FIGS. 2 and 3 illustrate that the thin film forming device 200 includes the plurality of source gas injection parts 241 to 245 which inject the silicon source gas to form the silicon thin film on the substrates W in the first space S1, the one plasma gas injection part 246 which injects the plasma gas in the second space S2 and the two purge gas injection parts 247 and 248 which inject the purge gas separating the first space S1 and the second space S2. However, it is to be noted that the numbers of source gas injection parts, plasma gas injection parts and purge gas injection parts may be appropriately adjusted.

In addition, as the occasion demands, some among the plurality of source gas injection parts 241 to 245 may be replaced with reaction gas injection parts which inject a reaction gas.

FIG. 4 is a representation of an example of a flow chart to assist in the explanation of a thin film forming method in accordance with an embodiment of the disclosure.

Referring to FIG. 4, the thin film forming method in accordance with the embodiment of the disclosure includes silicon thin film forming step S410, first purge gas supply step S420, plasma surface treatment step S430, second purge gas supply step S440 and thin film thickness checking step S450.

In the silicon thin film forming step S410, while a substrate which is placed on a substrate support passes through a first space being a silicon forming region as the substrate support in a process chamber is rotated, a silicon source gas is injected and thereby a silicon thin film is formed on the top of the substrate.

The thin film formed at this time may include an oxide film, an oxynitride film or a nitride film including silicon, or may include an SOH film which is used as a hard mask in a photolithography process.

The silicon thin film forming step S410 may include step of forming a silicon thin film on the substrate by chemical vapor deposition (CVD), atomic layer deposition (ALD) or selective epitaxial growth.

In the case where an amorphous silicon thin film is formed, a silicon source gas and a reaction gas may be simultaneously or sequentially supplied to the substrate so that only silicon atoms are adsorbed to or formed on the substrate.

A crystalline silicon thin film may be formed at a higher temperature than when an amorphous silicon thin film is formed, and the grain sizes of formed crystals may vary depending on a process temperature or other conditions.

On the other hand, in the case where a single-crystal silicon thin film is grown, a silicon source gas and a reaction gas serving as a reducing gas may be supplied to the substrate to allow silicon crystals to grow on the substrate.

The silicon thin film which is formed in the silicon forming region as the first space S1 may be a silicon single layer film or a silicon thin film having a thickness similar thereto. A small amount of impurities may be included in the silicon thin film, formed at this time, in addition to silicon. Further, the grain sizes of the crystals of the silicon thin film may not be uniform on the substrate, and there may be locally a region where silicon is not formed. Therefore, a process for treating the surface of the silicon thin film formed on the substrate is required.

In the first purge gas supply step S420, a purge gas is injected, and thereby, the silicon source gas remaining on the substrate is removed. Thereafter, when the substrate having passed through the silicon forming region passes through the second space S2 being a plasma treatment region, the silicon thin film formed on the substrate is exposed to plasma of hydrogen, nitrogen, argon or other inert gas.

In the plasma surface treatment step S430, the surface of the silicon thin film may be treated by the plasma of hydrogen, nitrogen, argon or other inert gas, and thereby, impurities adsorbed to or included in the silicon thin film may be removed.

In particular, the hydrogen plasma may be usefully used to remove impurities such as oxygen or carbon that may remain in the silicon thin film. Moreover, by the hydrogen plasma, the grain size of the crystals of the silicon thin film formed on the substrate may be made uniform or a variation in the grain size may be controlled.

In the second purge gas supply step S440, a purge gas is injected and the plasma gas remaining on the substrate is removed.

Then, by checking a thickness of the silicon thin film formed on the substrate (S450), the above-described procedure is repeated until the silicon thin film having a desired thickness is formed.

Meanwhile, as the occasion demands, in the silicon thin film forming step S410, step of implanting impurities into the silicon thin film may be performed simultaneously with or subsequently to the formation of the silicon thin film. When the substrate on which the silicon thin film is formed and for which the process of implanting impurities is performed passes through the second space S2 being the plasma treatment region, by removing the silicon thin film formed on the substrate or impurities in the silicon thin film by plasma such as hydrogen plasma, the concentration of impurities may be adjusted.

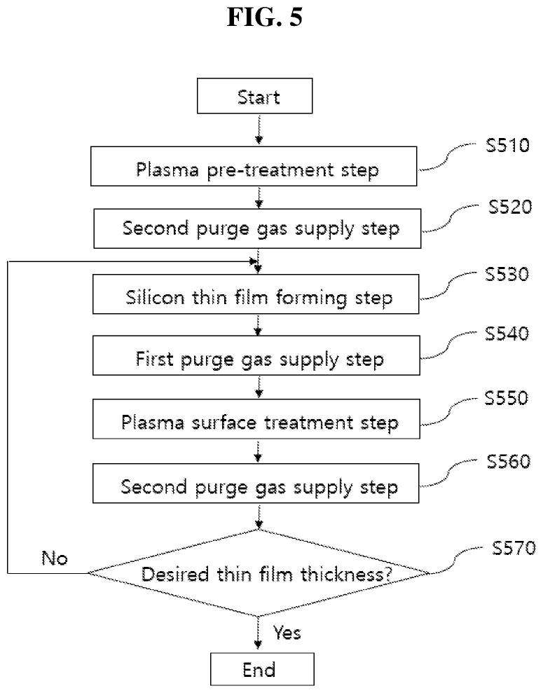

FIG. 5 is a representation of an example of a flow chart to assist in the explanation of a thin film forming method in accordance with another embodiment of the disclosure.

Referring to FIG. 5, the silicon thin film forming method in accordance with another embodiment of the disclosure includes plasma pre-treatment step S510, second purge gas supply step S520, silicon thin film forming step S530, first purge gas supply step S540, plasma surface treatment step S550, second purge gas supply step S560 and thin film thickness checking step S570.

Before the silicon thin film forming step S530, by performing first the plasma pre-treatment step S510 for a substrate in a plasma treatment region, a natural oxide film formed on the substrate or impurities adsorbed to or included in the surface of the substrate may be removed in advance.

Then, after removing a remaining plasma gas by supplying a purge gas (S520), the silicon thin film forming step S530 is performed.

Since the method illustrated in FIG. 5 is the same as the method illustrated in FIG. 4 except that the plasma pre-treatment step S510 and the second purge gas supply step S520 are performed before the silicon thin film forming step S530, detailed descriptions for the other processes will be omitted herein.

As is apparent from the above descriptions, with a trend that a pattern is complicated and the depth of the pattern increases, in the case where, as in the embodiments of the disclosure, a reaction space is divided in one process chamber, a silicon thin film is formed in a first space and a plasma surface treatment is performed in a second space, impurities in the thin film may be more efficiently removed and a uniform thin film may be formed on a pattern.

Also, impurities of a silicon thin film formed on the top, bottom and side of a pattern may be uniformly removed, and the grain size of the crystals of the silicon thin film may be made uniform.

While various embodiments have been described above, it will be understood to those skilled in the art that the embodiments described are by way of example only. Accordingly, the disclosure described herein should not be limited based on the described embodiments.

What is claimed is:

1. A thin film forming device comprising:
a process chamber providing a reaction space;
a substrate support installed in the process chamber and supporting a substrate;
a chamber lid covering a top of the process chamber; and
a gas injection module installed on a bottom surface of the chamber lid, and injecting a process gas to the substrate,
the reaction space comprising:
a first space for forming a silicon thin film on the substrate; and
a second space for processing a surface of the substrate which is formed with the silicon thin film, by using plasma,
wherein the substrate is moved to the first space and the second space by rotation of the substrate support.

2. The thin film forming device according to claim 1, wherein the first space is a silicon forming region where the silicon thin film is formed on the substrate by chemical vapor deposition (CVD), atomic layer deposition (ALD) or selective epitaxial growth.

3. The thin film forming device according to claim 2, wherein the silicon thin film is an amorphous silicon thin film, a crystalline silicon thin film or a single-crystal silicon thin film.

4. The thin film forming device according to claim 1, wherein the second space is a plasma treatment region where the silicon thin film formed on the substrate is exposed to plasma of an inert gas to remove impurities in the silicon thin film or make a grain size of the silicon thin film uniform.

5. The thin film forming device according to claim 1, wherein the gas injection module comprises:
a source gas injection part injecting a source gas to the substrate in the first space;
a plasma gas injection part injecting a plasma gas to the substrate in the second space; and
a purge gas injection part injecting a purge gas between the first space and the second space.

6. The thin film forming device according to claim 5, further comprising:
a reaction gas injection part injecting a reaction gas to the substrate in the first space.

7. The thin film forming device according to claim 1, wherein the silicon thin film has a thickness of 1 to 20 Å.

8. The thin film forming device according to claim 5,
wherein the source gas injection part comprises a plurality of source gas injectors, and
wherein the plurality of source gas injectors inject the same source gas or different source gases.

9. A thin film forming method comprising:
silicon thin film forming step of forming a silicon thin film by supplying a silicon source gas on a substrate in a first space in a process chamber;
first purge gas supply step of supplying a first purge gas;
plasma surface treatment step of treating a surface of the silicon thin film by using plasma in a second space in the process chamber to remove impurities in the silicon thin film or make a grain size of the silicon thin film uniform; and
second purge gas supply step of supplying a second purge gas.

10. The thin film forming method according to claim 9, wherein the silicon thin film forming step comprises any one among step of forming an amorphous silicon thin film, step of forming a crystalline silicon thin film and step of growing single-crystal silicon.

11. The thin film forming method according to claim 9, wherein the silicon thin film forming step comprises forming the silicon thin film on the substrate by chemical vapor deposition (CVD), atomic layer deposition (ALD) or selective epitaxial growth.

12. The thin film forming method according to claim 9, wherein the plasma surface treatment step comprises treating the surface of the silicon thin film by exposing the silicon thin film to plasma of at least one gas among hydrogen (H₂), nitrogen (N₂), argon (Ar) and an inert gas.

13. The thin film forming method according to claim 9, further comprising:
thin film thickness checking step of checking a thickness of the silicon thin film formed on the substrate,
wherein the silicon thin film forming step to the second purge gas supply step are repeated until the silicon thin film having a desired thickness is formed.

14. A thin film forming method comprising:
plasma pre-treatment step of treating a surface of a substrate by using plasma in a second space in a process chamber to remove a natural oxide film formed on the surface or impurities included in the surface of the substrate;
second purge gas supply step of supplying a second purge gas;
silicon thin film forming step of forming a silicon thin film by supplying a silicon source gas on the substrate in a first space in the process chamber;
first purge gas supply step of supplying a first purge gas;
plasma surface treatment step of treating a surface of the silicon thin film by using plasma in the second space in the process chamber to remove impurities in the silicon thin film or make a grain size of the silicon thin film uniform; and
second purge gas supply step of supplying a second purge gas.

15. The thin film forming method according to claim 14, further comprising:
thin film thickness checking step of checking a thickness of the silicon thin film formed on the substrate,
wherein the silicon thin film forming step to the second purge gas supply step are repeated until the silicon thin film having a desired thickness is formed.

16. The thin film forming device according to claim 1, wherein the process chamber further comprises:
a first purge space as a region where a purge gas is injected between the first space and the second space to remove a source gas remaining on the substrate; and
a second purge space as a region where a purge gas is injected between the second space and the first space to remove a plasma gas remaining on the substrate.

17. The thin film forming device according to claim 16, wherein the first space, the first purge space, the second space and the second purge space are spaces which are separated physically or in terms of time.
